(19) United States
(12) Patent Application Publication
(10) Pub. No.: US 2013/0327384 A1
(43) Pub. Date: Dec. 12, 2013

(54) MULTI-JUNCTION SOLAR CELL AND MANUFACTURING METHOD THEREFOR

(71) Applicants: Hirotaka Endo, Wako-shi (JP); Hajime Goto, Wako-shi (JP); Takanori Maebashi, Wako-shi (JP); Mitsutaka Nishijima, Wako-shi (JP); Natsuo Nakamura, Wako-shi (JP)

(72) Inventors: Hirotaka Endo, Wako-shi (JP); Hajime Goto, Wako-shi (JP); Takanori Maebashi, Wako-shi (JP); Mitsutaka Nishijima, Wako-shi (JP); Natsuo Nakamura, Wako-shi (JP)

(73) Assignee: HONDA MOTOR CO., LTD., Tokyo (JP)

(21) Appl. No.: 14/001,056

(22) PCT Filed: Mar. 16, 2012
(86) PCT No.: PCT/JP2012/056906

§ 371 Date: Aug. 22, 2013

Related U.S. Application Data
(60) Provisional application No. 61/453,196, filed on Mar. 16, 2011.

(30) Foreign Application Priority Data
Mar. 16, 2011 (JP) 2011 057814

(51) Int. Cl. H01L 31/0725

(52) U.S. Cl. CPC H01L 31/0725
USPC 136/255; 438/94

(57) ABSTRACT

The present invention provides a multi-junction solar cell capable of increasing the degree of freedom of the selection of compound semiconductors. The multi-junction solar cell 1 includes a layered structure section 4 including compound semiconductor photovoltaic devices 2 and 3 matched in lattice constant with each other and joined to each other, and a nanopillar structure section 7 including a compound semiconductor photovoltaic device or a plurality of compound semiconductor photovoltaic devices 5 and 6 joined to each other.

### TECHNICAL FIELD

The present invention relates to a multi junction solar cell and a manufacturing method therefor.

### BACKGROUND ART

There has hitherto been known a multi-junction solar cell using thin layered compound semiconductors as photovoltaic devices, wherein the compound semiconductor photovoltaic devices, different in band gap energy from each other, are mutually laminated for the purpose of improving the conversion efficiency.

In the multi junction solar cell, the compound semiconductor photovoltaic device having the largest band gap energy is arranged as the outermost layer, and a plurality of the other compound semiconductor photovoltaic devices are sequentially laminated, in descending order of band gap energy. In this way, with respect to the sunlight incident on the multi-junction solar cell, first in the outermost layer of the compound semiconductor photovoltaic device, the photons each having an energy larger than the band gap energy of the compound semiconductor photovoltaic device are absorbed and photoelectrically converted, and the other photons pass through. Next, in the second compound semiconductor photovoltaic device, the photons each having an energy larger than the band gap energy of the second compound semiconductor photovoltaic device and smaller than the band gap energy of the compound semiconductor photovoltaic device of the outermost layer are absorbed and photoelectrically converted, and the other photons pass through.

By sequentially repeating such a process, and by summing up the electromotive forces obtained by the individual compound semiconductor photovoltaic devices, an electromotive force larger than the electromotive force obtained with a single compound semiconductor photovoltaic device can be obtained, and thus the conversion efficiency can be improved.

However, in the multi-junction solar cell, when the lattice constants are mismatched between the two compound semiconductor photovoltaic devices laminated to be adjacent to each other, there occurs a problem such that a defect referred to as the threading dislocation is created in the heterojunction interface between the two photovoltaic devices. The threading dislocation functions so as to recombine the electron and the hole generated by the photoelectric conversion, and hence the electric charge is lost in the multi-junction solar cell to impede the improvement of the conversion efficiency.

Accordingly, there has been proposed a technique in which a buffer layer is disposed between the two compound semiconductor photovoltaic devices mismatched in lattice constant (for example, see Patent Literature 1). The buffer layer has a structure in which the electron concentration and the hole concentration are extremely different from each other, and even when the threading dislocation occurs, the loss of the electric charge caused by the recombination of electron and hole can be reduced. However, the technique in which the buffer layer is disposed premises the occurrence of the threading dislocation, and hence is not completely free from the loss of the electric charge.

Accordingly, in conventional multi-junction solar cells, compound semiconductor photovoltaic devices mutually matched in lattice constant are joined.

### CITATION LIST

### Patent Literature

Patent Literature 1: Japanese Patent Laid-Open No. 2010-182951

### SUMMARY OF INVENTION

### Technical Problem

However, when the compound semiconductor photovoltaic devices mutually matched in lattice constant are used, there is an inconvenience such that the types of the usable compound semiconductors are limited.

An object of the present invention is to provide a multi-junction solar cell capable of solving such an inconvenience and increasing the degree of freedom of the selection of the compound semiconductor.

### Solution to Problem

For the purpose of achieving such an object, the multi-junction solar cell of the present invention is a multi-junction solar cell, including a plurality of compound semiconductor photovoltaic devices, different in band gap energy from each other, arranged in such a way that the nearer the incident side of sunlight, the larger the band gap energy, with each of the cells being joined to each other through the intermediary of a tunnel junction layer, wherein the multi-junction solar cell includes a layered structure section including compound semiconductor photovoltaic devices matched in lattice constant with each other and laminated to be joined to each other, and a nanopillar structure section including a compound semiconductor photovoltaic device or a plurality of compound semiconductor photovoltaic devices joined to each other; and the nanopillar structure section includes a compound semiconductor photovoltaic device mismatched in lattice constant with the compound semiconductor photovoltaic devices constituting the layered structure section, or a plurality of compound semiconductor photovoltaic devices mismatched in lattice constant with each other and joined to each other.

In the multi junction solar cell of the present invention, the nanopillar structure section includes a compound semiconductor photovoltaic device mismatched in lattice constant with the compound semiconductor photovoltaic devices constituting the layered structure section. Alternatively, the nanopillar structure section includes a plurality of compound semiconductor photovoltaic devices mismatched in lattice constant with each other and joined to each other. Consequently, the deformation of the external form of the nanopillar structure section absorbs the strain due to the threading dislocation caused by the mismatch of the lattice constant, and hence the occurrence of the threading dislocation can be prevented.

Therefore, according to the multi-junction solar cell of the present invention, a combination of compound semiconductors mismatched in lattice constant with each other can also be used, and hence the degree of freedom of the selection of compound semiconductors can be increased.

In the multi junction solar cell of the present invention, the compound semiconductor photovoltaic devices mismatched in lattice constant with each other preferably have the mismatch of the lattice constant of 2.5% or less. The mismatch of the lattice constant of 2.5% or less in the compound semiconductor photovoltaic devices mismatched in lattice constant with each other allows the strain due to the mismatch of the lattice constant to be certainly absorbed by the deformation of the external form of the nanopillar structure section.

In this case, when the diameter of the inscribed circle of the cross section of the nanopillar structure section is represented by d, the diameter d is preferably 0.65 μm or less. The nanopillar structure section can certainly absorb the strain due to the mismatch of the lattice constant through the distortion of the external form thereof, within the range of the diameter d of the inscribed circle of 0.65 μm or less, when the mismatch of the lattice constant is 2.5% or less.

In the multi junction solar cell of the present invention, when the nanopillar structure section includes compound semiconductor photovoltaic devices mismatched in lattice constant with the compound semiconductor photovoltaic devices constituting the layered structure section, the compound semiconductor photovoltaic devices forming the nanopillar structure section are preferably joined to the layered structure section through the intermediary of the nanopillar structure section including the compound semiconductors matched in lattice constant with the compound semiconductor photovoltaic devices constituting the layered structure section.

When such structure is adopted, the junction section mismatched in lattice constant is wholly included in the nanopillar structure section. Accordingly, the multi junction solar cell of the present invention having the foregoing constitution can more certainly absorb the strain due to the mismatch of the lattice constant through the deformation of the external form of the nanopillar structure section.

In the multi junction solar cell of the present invention, the layered structure section is preferably disposed on the sunlight incident side, and the nanopillar structure section is preferably disposed on the side opposite to the sunlight incident side. In the compound semiconductors, as the compound semiconductor having the largest band gap and the compound semiconductor having the second largest band gap, compound semiconductors matched in lattice constants can be used.

Accordingly, photoelectric conversion can be performed efficiently by constituting the layered structure section with the compound semiconductor having the largest band gap and the compound semiconductor having the second largest band gap, and by arranging the layered structure section on the sunlight incident side. The compound semiconductor having the largest band gap and the compound semiconductor having the second largest band gap are matched in lattice constant, and hence are not required to form the nanopillar structure.

In this case, in the multi-junction solar cell of the present invention, the layered structure section is preferably formed by mutually laminating and joining two compound semiconductor photovoltaic devices matched in lattice constant with each other. According to the multi junction solar cell having the foregoing constitution, the layered structure section is formed by laminating and joining the two compound semiconductor photovoltaic devices respectively including the compound semiconductor having the largest band gap and the compound semiconductor having the second largest band gap. By making the third and subsequent layers, following the foregoing two layers, form the nanopillar structure section, the strain due to the mismatch of the lattice constant can be efficiently absorbed by the distortion of the external form of the nanopillar structure section.

In the multi junction solar cell of the present invention, the nanopillar structure section preferably includes a passivation layer to coat the surface of the nanopillar structure section. In general, in a compound semiconductor photovoltaic device, the electrons and the holes generated inside the cell partially diffuse toward the surface and are recombined on the surface to cause the loss of electric charge. In this connection, the multi-junction solar cell of the present invention can efficiently perform photoelectric conversion by having the passivation layer to coat the surface of the nanopillar structure section.

In the multi junction solar cell of the present invention, for example, the layered structure section can include a first compound semiconductor photovoltaic device forming the outermost layer, and a second compound semiconductor photovoltaic device laminated on and joined to the first compound semiconductor photovoltaic device; and the nanopillar structure section includes a third compound semiconductor photovoltaic device joined to the second compound semiconductor photovoltaic device and a fourth compound semiconductor photovoltaic device joined to the third compound semiconductor photovoltaic device.

In this case, the first compound semiconductor photovoltaic device can include In_{0.48}(Al_{α}Ga_{1-α})_{0.52}P(0≦α≦0.7); the second compound semiconductor photovoltaic device can include Al_{β}Ga_{1-β}As(0≦β0.45); the third compound semiconductor photovoltaic device can include Ga_{γ}In_{1-γ}As(0.65≦γ<1); and the fourth compound semiconductor photovoltaic device can include Ga_{δ}In_{1-δ}As(γ−0.35≦δ<γ).

Alternatively, in the multi junction solar cell of the present invention, for example, the layered structure section can include a first compound semiconductor photovoltaic device forming the outermost layer, and a second compound semiconductor photovoltaic device laminated on and joined to the first compound semiconductor photovoltaic device; and the nanopillar structure section can include a third compound semiconductor photovoltaic device joined to the second compound semiconductor photovoltaic device.

In this case, for example, the first compound semiconductor photovoltaic device can include In_{0.48}(Al_{α}Ga_{1-α})_{0.52}P(0≦α≦0.7); the second compound semiconductor photovoltaic device can include Al_{β}Ga_{1-β}As(0≦β≦0.45); and the third compound semiconductor photovoltaic device can include Ga_{γ}In_{1-γ}As(0.65≦γ<1).

The manufacturing method for a multi-junction solar cell of the present invention includes: a step of forming, by growing a crystal on a growth substrate, a layered structure section including compound semiconductor photovoltaic devices matching in lattice constant, laminated on and joined to each other; a step of forming a coating layer, on the surface of the compound semiconductor photovoltaic devices forming the layered structure section, while exposing an area for forming thereon the nanopillar structure section to be joined to the layered structure section, and coating the areas other than the area for forming the nanopillar structure section; a step of forming a plurality of nanopillar structure sections each including at least one compound semiconductor photovoltaic device by epitaxially growing crystals on the area exposed from the coating layer on the surface of the compound semiconductor photovoltaic devices forming the layered structure section; a step of forming a reinforcing layer for reinforcing the nanopillar structure sections by filling an insulating material in the gaps between the plurality of nanopillar structure sections and by embedding the plurality of nanopillar structure sections with the insulating material; a step of exposing the tips of the plurality of nanopillar structure sections by partially removing the insulating material; a step of forming a first electrode connected to the tips of the exposed plurality of nanopillar structure sections; a step of forming a supporting substrate on the first electrode; a step of exposing the layered structure section by removing the growth substrate; and a step of forming a second electrode connected to the surface of the exposed layered structure section.

In the manufacturing method of the present invention, the reinforcing layer can be formed by the atomic layer deposition method using, for example, an insulating material including an inorganic compound.

### BRIEF DESCRIPTION OF DRAWINGS

FIG. 1 is an explanatory cross-sectional view illustrating an example of the structure of the multi-junction solar cell of the present invention.

FIG. 2 is an explanatory cross-sectional view of the nanopillar structure section in the multi-junction solar cell shown in FIG. 1.

FIG. 3 is an explanatory cross-sectional view illustrating another example of the structure of the multi-junction solar cell of the present invention.

FIGS. 4A, 4B and 4C are explanatory cross-sectional views illustrating the manufacturing steps of the multi-junction solar cell of the present invention shown in FIG. 1.

FIG. 5 is an electron micrograph showing the cross section of the substrate on which a nanopillar having a mismatch of the lattice constant of 2.5% was grown.

FIG. 6 is an electron micrograph showing the cross section of a substrate on which a nanopillar having a mismatch of the lattice constant of 3.2% was grown.

FIG. 7 is an electron micrograph showing the cross section of a substrate on which a nanopillar having a mismatch of the lattice constant of 2.5% and a diameter of 0.65 μm of the circle inscribed in the cross section was grown.

FIG. 8 is an electron micrograph showing the cross section of a substrate on which a top cell, a second cell, a strain relaxation layer, a third cell and a bottom cell were formed.

FIG. 9 is a graph showing the difference of the external quantum efficiency due to the presence and absence of the passivation layer.

FIG. 10 is a set of electron micrographs, with FIG. 10A showing the surface of the substrate before and FIG. 10B showing the surface of the substrate after the formation of a reinforcing layer.

### DESCRIPTION OF EMBODIMENTS

Next, the embodiments of the present invention are described in more detail with reference to the accompanying drawings.

As shown in FIG. 1, the multi junction solar cell 1 of the present embodiment includes a layered structure section 4 composed of a first compound semiconductor photovoltaic device (top cell) 2 forming the outermost layer, and a second compound semiconductor photovoltaic device (second cell) 3 laminated on and joined to the top cell. The multi-junction solar cell 1 also includes a nanopillar structure section 7 composed of a third compound semiconductor photovoltaic device (third cell) 5 joined to the second cell 3, and a fourth compound semiconductor photovoltaic device (bottom cell) 6 joined to the third cell 5. Consequently, the multi-junction solar cell 1 forms a four-junction solar cell.

The multi junction solar cell 1 includes not-shown tunnel junction layers, respectively, between the top cell 2 and the second cell 3, between the second cell 3 and the third cell 5, and between the third cell 5 and the bottom cell 6. The top cell 2, the second cell 3, the third cell 5 and the bottom cell 6 each include a not-shown p-n junction in the interior thereof.

In the multi junction solar cell 1, it is designed that the sunlight is made incident from the side of the top cell 2 forming the outermost layer. Accordingly, in the multi-junction solar cell 1, the top cell 2, the second cell 3, the third cell 5 and the bottom cell 6 are arranged in such a way that the nearer the top cell 2, the larger the band gap energy.

In the multi junction solar cell 1, the top cell 2 and the second cell 3 are formed with compound semiconductors matched in lattice constant. On the other hand, the third cell 5 is mismatched in lattice constant with the second cell 3, and the bottom cell 6 is mismatched in lattice constant with the third cell 5. However, in the multi-junction solar cell 1, by forming the nanopillar structure section 7 with the third cell 5 and the bottom cell 6, the strain due to the mismatch of the lattice constant is absorbed by the deformation of the external form of the nanopillar structure section 7, and thus the occurrence of the threading dislocation can be prevented.

The surface of the nanopillar structure section 7 is coated with a passivation layer 8, and a transparent insulating material layer 9 is disposed between the passivation layer 8 and the second cell 3. Between the respective nanopillar structure sections 7, a filler 10 is filled.

The top cell 2 can be formed of, for example, In_{0.49}(Al_{α}Ga_{1-α})_{0.51}P(0≦α<0.7), and the second cell 3 can be formed of, for example, Al_{β}Ga_{1-β}As(0≦β≦0.45). Consequently, the top cell 2 and the second cell 3 can be matched in lattice constant with each other.

When α is larger than 0.7 in In_{0.49}(Al_{α}Ga_{1-α})_{0.51}P forming the top cell 2, this semiconductor becomes an indirect gap semiconductor and hardly absorbs light. When β is larger than 0.45 in Al_{β}Ga_{1-β}As forming the second cell 3, this semiconductor becomes an indirect gap semiconductor and hardly absorbs light.

For the third cell 5 and the bottom cell 6, in the multi-junction solar cell 1 of the present embodiment, materials not matched in lattice constant respectively with the adjacent cells can be used because the strain due to the mismatch of the lattice constant can be absorbed by the deformation of the external form of the nanopillar structure section 7. Consequently, the degree of freedom of the selection of the compound semiconductors used for the third cell 5 and the bottom cell 6 can be increased.

In the multi-junction solar cell 1, the mismatch of the lattice constant is preferably 2.5% or less, for the purpose of allowing the strain due to the mismatch of the lattice constant to be certainly absorbed by the deformation of the external form of the nanopillar structure section 7.

Accordingly, the third cell 5 can be formed of, for example, Ga_{γ}In_{1-γ}As(0.65≦γ<1) and the bottom cell 6 can be formed of, for example, Ga_{δ}In_{1-δ}As(γ−0.35≦δ<γ). Consequently, the mismatch of the lattice constant of the third cell 5 in relation to the second cell 3 and the mismatch of the lattice constant of the bottom cell 6 in relation to the third cell 5 can be both made to fall within a range of 2.5% or less.

When γ is less than 0.65 in Ga_{γ}In_{1-γ}As forming the third cell 5, the mismatch of the lattice constant of the third cell 5 in relation to the second cell 3 cannot be made to fall within the range of 2.5% or less. When γ=1, inappropriately the material of the third cell 5 becomes GaAs.

When δ is equal to or larger than γ in Ga_{δ}In_{1-δ}As forming the bottom cell 6, the band gap of the bottom cell 6 cannot be made smaller in relation to the band gap of the third cell 5. When δ is equal to or less than (γ−0.35) in Ga_{δ}In_{1-δ}As forming the bottom cell 6, the mismatch of the lattice constant of the bottom cell 6 in relation to the third cell 5 cannot be made to fall within a range of 2.5% or less.

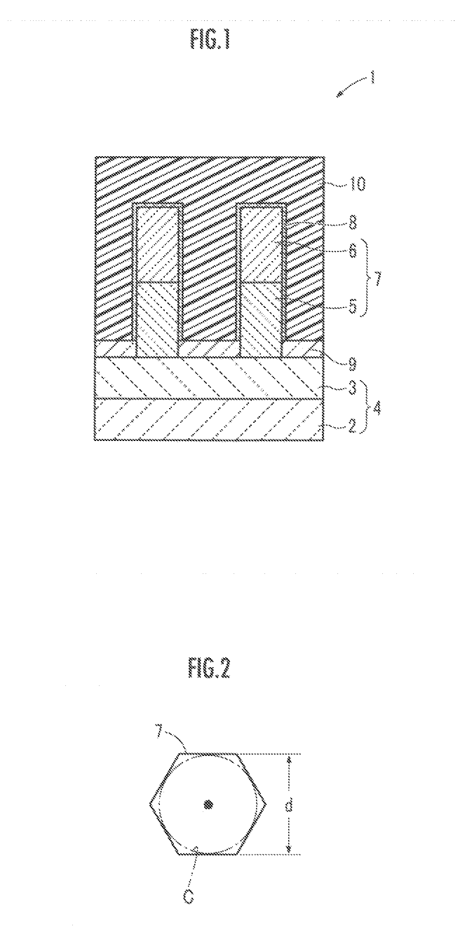

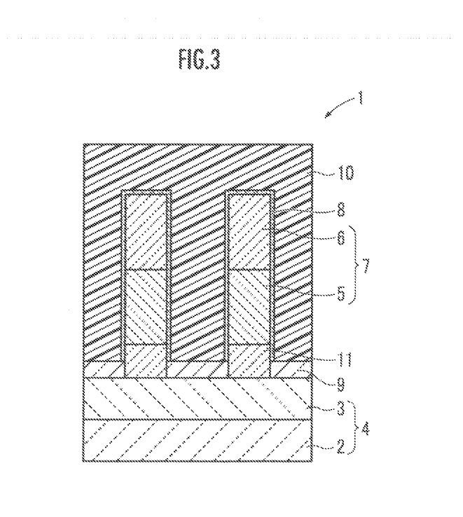

In the multi junction solar cell 1, the nanopillar structure section 7 has a regular hexagonal cross-sectional shape as shown in FIG. 2. As shown in FIG. 2, when the diameter of the inscribed circle C of the nanopillar structure section 7 is represented by d, the diameter d is preferably 0.65 γm or less for the purpose of allowing the strain due to the mismatch of the lattice constant to be further certainly absorbed by the distortion of the external form of the nanopillar structure section 7; the smaller the diameter d, the more advantageous. In the case where the diameter d of the inscribed circle C of the nanopillar structure section 7 is larger than 0.65 γm, even when the mismatch of the lattice constant falls within a range of 2.5% or less, the strain due to the mismatch cannot be absorbed by the deformation of the external form of the nanopillar structure section 7 in some cases.

The top cell 2, the second cell 3, the third cell 5 and the bottom cell 6 may each have a window layer on the sunlight incident side and a BSF (Back Surface Field) layer on the back surface side.

The passivation layer 8 can be formed of, for example, AlInP The transparent insulating material layer 9 can be formed of, for example, SiO₂, SiN_{X}, Al₂O₃, ZnS and tungsten.

Examples of the filler 10 to be filled between the respective nanopillar structure sections 7 include; SiO₂, SiNₓ, Al₂O₃, In₂O₃, SnO₃, HfO₂, ZrO₂, TiO₂, SiC, AlP, AlAs, AlSb, AlN, GaP, GaAs, GaN, GaS, InP, ZnO, ZnS, ZnSe, ZnTe, CdS, CdSe, CdTe, BCB resin (divinyltetramethylsiloxane-benzocyclobutene resin, trade name: Cyclotene 3022-35, manufactured by Dow Chemical Co.), SiO₂, SiOF, Si—H-containing SiO₂, SiOC, methyl group-containing SiO₂, polyimide polymer film, paraxylylene polymer film, fluorine-doped amorphous carbon, aromatic hydrocarbon polymer, polyaryl ether material, silica glass, phenolic resin, epoxy resin, melamine resin, urea resin, unsaturated polyester resin, alkyd resin, polyurethane, polyethylene, polypropylene, polyvinyl chloride, polystyrene, polyvinyl acetate, polytetrafluoroethylene, acrylonitrile-butadiene-styrene resin, acrylonitrile-styrene copolymer resin, acrylic resin, polyamide, polyacetal, polycarbonate, modified polyphenylene ether, polybutylene terephthalate, polyethylene terephthalate, cyclic polyolefin, polyphenylene sulfide, polysulfone, polyether sulfone, amorphous polymer, polyether ether ketone, thermoplastic polyimide, polyamide imide, acrylic rubber, nitrile rubber, isoprene rubber, urethane rubber, ethylene-propylene rubber, epichlorohydrin rubber, chloroprene rubber, silicone rubber, styrene-butadiene rubber, butadiene rubber, fluororubber and polyisobutylene.

The filler 10 to be filled between the respective nanopillar structure sections 7 is particularly preferably an insulating material made of an inorganic compound. Examples of such an insulating material include: inorganic compounds such as SiO₂, SiNₓ, Al₂O₃, In₂O₃, SnO₃, HfO₂, ZrO₂, TiO₂, SiC, AlP, AlAs, AlSb, MN, GaP, GaAs, GaN, GaS, InP, ZnO, ZnS, ZnSe, ZnTe, CdS, CdSe and CdTe.

Next, another embodiment of the multi-junction solar cell 1 is described with reference to FIG. 3. The multi-junction solar cell 1 shown in FIG. 3 has exactly the same structure as in the multi-junction solar cell 1 shown in FIG. 1 except that the third cell 5 is joined to the second cell 3 through the intermediary of a strain relaxation layer 11 having nanopillar structure. Here, the strain relaxation layer 11 is formed of a compound semiconductor matched in lattice constant with the second cell 3.

According to the multi-junction solar cell 1 shown in FIG. 3, the second cell 3 and the strain relaxation layer 11 are matched in lattice constant with each other, but the third cell 5 is mismatched in lattice constants with the strain relaxation layer 11, and the bottom cell 6 is mismatched in lattice constant with the third cell 5. Consequently, the junctions mismatched in lattice constant are all included in the nanopillar structure section 7.

Accordingly, according to the multi-junction solar cell 1 shown in FIG. 3, the strain due to the mismatch of the lattice constant can be more certainly absorbed by the deformation of the external form of the nanopillar structure section 7.

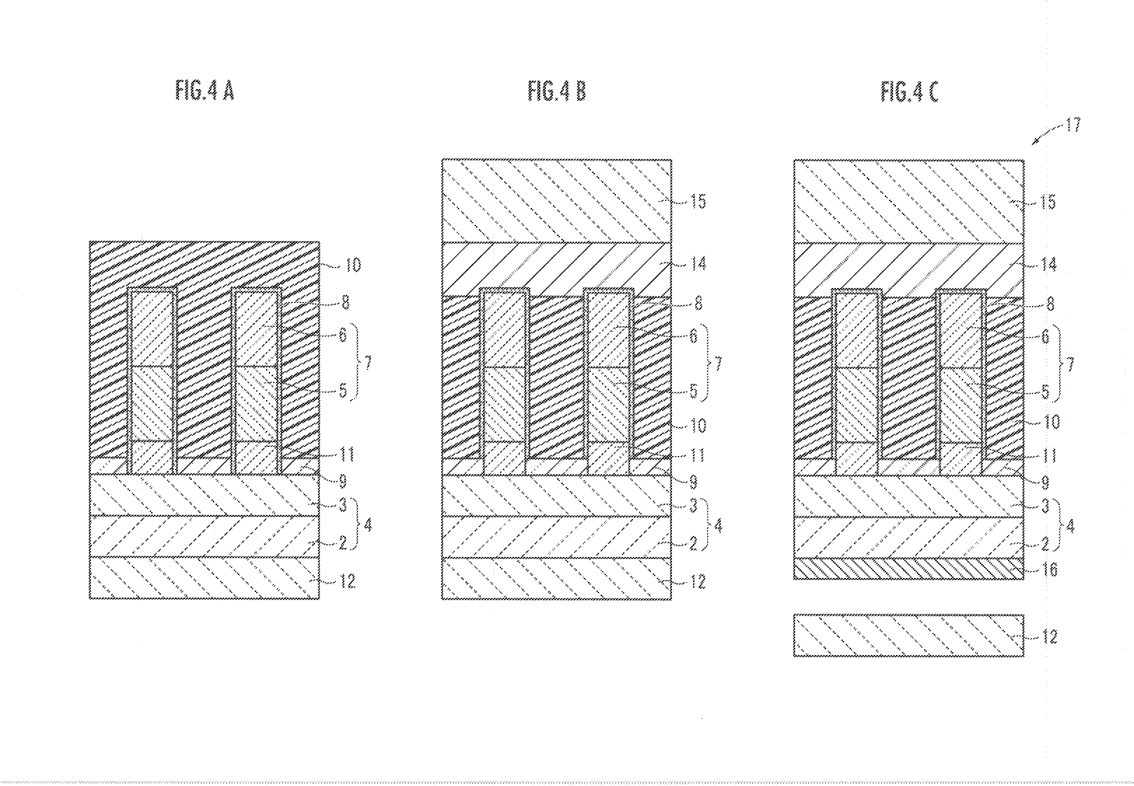

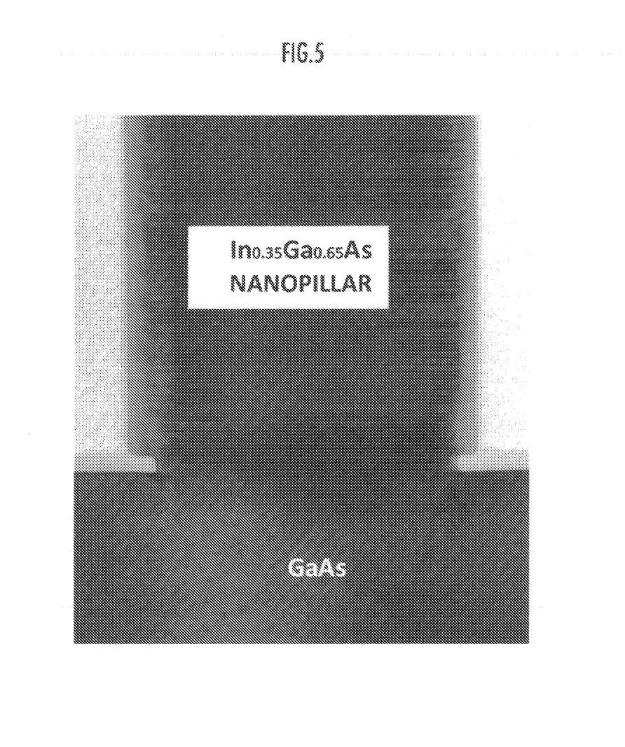

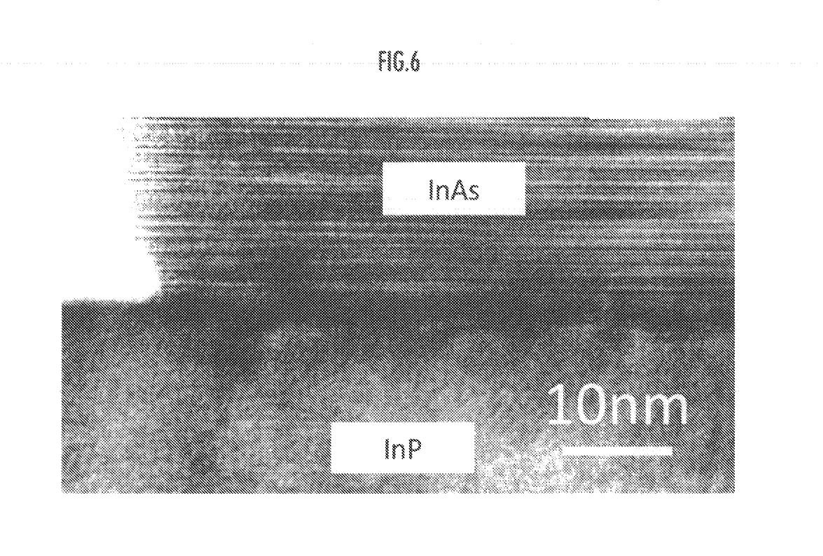

Next, an example of the manufacturing method for the multi-junction solar cell 1 of the present embodiment is described with reference to FIG. 4.

First, by growing a crystal on the growth substrate 12 shown in FIG. 4A, the thin film-shaped top cell 2 is formed through the intermediary of a not-shown etching stop layer and a not-shown cap layer. Next, on the top cell 2, through the intermediary of a not-shown tunnel junction layer, the thin film-shaped second cell 3 formed of a compound semiconductor matched in lattice constant with the top cell 2. Next, on the second cell 3, the not-shown tunnel junction layer is formed. Consequently, on the growth substrate 12, it is possible to form the layered structure section 4 in which the top cell 2 and the second cell 3, matched in lattice constant with each other, are laminated on and joined to each other through the intermediary of the tunnel junction layer.

As the growth substrate 12, a GaAs(111)B substrate can be used. The crystal growth can be performed by setting the growth substrate 12 in a MOVPE apparatus, and by sequentially feeding the flows of the mixed gases respectively including the materials of the etching stop layer, the cap layer, the top cell 2, the second cell 3, and the respective tunnel junction layers.

Next, on the surface of the second cell 3, the transparent insulating material layer 9 made of SiO₂ is formed. The transparent insulating material layer 9 is formed on the surface of the second cell 3 in such a way that the area for forming the nanopillar structure section 7 to be joined to the second cell 3 is exposed and the other area is coated with the transparent insulating material layer 9.

When the transparent insulating material layer 9 is formed, an amorphous SiO₂ coating film is formed on the second cell 3, and a positive resist is applied thereto. Next, on the area for formation of the nanopillar structure section 7, a corresponding predetermined pattern is drawn, then the positive resist is developed, and the amorphous SiO₂ coating film in the pattern is removed by etching. After the etching, the positive resist is removed.

The amorphous SiO₂ coating film can be formed, for example, by using an RF sputtering apparatus equipped with a SiO₂ target. The predetermined pattern can be formed, for example, by drawing with an EB drawing apparatus. The etching can be performed, for example, with a buffered hydrofluoric acid (BHF) aqueous solution prepared by dilution by a factor of 50.

Next, on the area, exposed from the transparent insulating material layer 9, of the second cell 3, a crystal is epitaxially grown to form the strain relaxation layer 11. Next, the third cell 5 is formed by epitaxially growing a crystal on the end of the strain relaxation layer 11, and the bottom cell 6 is formed by epitaxially growing a crystal on the end of the third cell 5 through the intermediary of the not-shown tunnel junction layer. Consequently, it is possible to form, on the second cell 3, a plurality of the nanopillar structure sections 7 in each of which the strain relaxation layer 11, the third cell 5 and the bottom cell 6 are joined to each other respectively through the intermediary of the tunnel junction layers.

The epitaxial growth can be performed by setting the growth substrate 12 having the transparent insulating material layer 9 formed on the second cell 3 in a MOVPE apparatus, and by sequentially feeding the flows of the mixed gases respectively including the materials of the strain relaxation layer 11, the third cell 5, the bottom cell 6, and the respective tunnel junction layers.

Next, on the surface of the nanopillar structure section 7, the passivation layer 8 is formed. The formation of the passivation layer 8 can be performed by using the growth substrate 12 having the transparent insulating material layer 9 and the nanopillar structure section 7 formed on the second cell 3, and by feeding the flow of the mixed gas including the materials of the passivation layer 8.

Next, the reinforcing layer 10 for reinforcing the nanopillar structure sections 7 by filling an insulating material in the gaps between the plurality of nanopillar structure sections 7 and by embedding the plurality of nanopillar structure sections 7 with the insulating material. The formation of the reinforcing layer 10 can be performed by setting the growth substrate 12 having the passivation layer 8 formed on the surface of the nanopillar structure section 7, in an atomic layer deposition apparatus.

Next, as shown in FIG. 4B, the insulating material forming the reinforcing layer 10 is partially removed to expose the tips of the nanopillar structure sections 7. The partial removal of the insulating material can be performed by setting the growth substrate 12 having the reinforcing layer 10 formed thereon in a reactive ion etching (RIE) apparatus, and by selectively etching the insulating material.

Next, a first electrode 14 to be ohmic-connected to the exposed tips of the plurality of the nanopillar structure sections 7 is formed, and a supporting substrate 15 is formed on the first electrode 14. The first electrode 14 is, for example, an Au/Ti electrode, and can be formed by resistance heating vapor deposition or by electron beam vapor deposition of Au and Ti on the exposed tips of the plurality of the nanopillar structure sections 7. The supporting substrate 15 is, for example, a Si substrate on the surface of which an Au film is formed, and can be formed by joining on the first electrode 14.

Next, as shown in FIG. 4C, the growth substrate 12 is removed. The removal of the growth substrate 12 can be performed by selectively etching the growth substrate 12. The etching is stopped by the etching stop layer. The etching stop layer is, for example, a layer formed of n⁺-In_{0.48}Ga_{0.52}P, and can be removed, separately from the growth substrate 12, by etching with hydrochloric acid.

Next, a second electrode 16 is formed on the area of the cap layer exposed by the removal of the growth substrate 12, then the surface of the top cell 2 is exposed by removing the area not coated with the second electrode 16 of the cap layer, and thus a multi junction solar cell 17 equipped with the electrodes is obtained. The second electrode 16 is, for example, an AuGe/Ni electrode, and can be formed by disposing an electrode formation mask on the cap layer and by resistance heating vapor deposition or by electron beam vapor deposition of AuGe and Ni on the cap layer. The cap layer is, for example, a layer formed of n⁺-GaAs, and only the area of the cap layer, not coated with the second electrode 16, is removed by etching with hydrogen peroxide water and a phosphoric acid aqueous solution to expose the surface of the top cell 2.

The manufacturing method is described by taking as an example the case of the multi-junction solar cell 1 having the strain relaxation layer 11; however, the formation of the strain relaxation layer 11 may be omitted, and in such a case, the multi-junction solar cell 1 having the structure shown in FIG. 1 is formed.

In the present embodiment, the case where the multi-junction solar cell 1 is a four-junction solar cell is described; however, the multi-junction solar cell 1 may also be a three-junction solar cell. The three-junction solar cell corresponds to the multi-junction solar cells 1 shown in FIGS. 1 and 3, having no bottom cell 6.

Such three-junction solar cells can be manufactured by the same manufacturing method as the foregoing manufacturing method except that the bottom cell 6 is not formed.

Next, Examples and Comparative Examples of the present invention are presented.

### EXAMPLES

### Example 1

In present Example, first, a GaAs(111)B substrate was cleaned, and then, by using an RF sputtering apparatus equipped with a SiO₂ target, an amorphous SiO₂ coating film was formed in a thickness of about 30 nm, on the GaAs(111)B substrate, as a transparent insulating material layer. Next, a positive resist was applied to the transparent insulating material layer by spin coating.

Next, on the positive resist, by using an EB drawing apparatus, a pattern of circular holes of 200 nm in diameter arranged with a pitch of 400 nm (the center-to-center distance between the adjacent circular holes was 400 nm) in a triangular lattice shape was drawn. After the drawing, the resist was developed, the amorphous SiO₂ coating film in the circular holes was removed by etching with a buffered hydrofluoric acid (BHF) aqueous solution, and after the etching, the resist was removed.

Next, the GaAs(111)B substrate having an amorphous SiO₂ coating film (transparent insulating material layer) formed thereon was set in a MOVPE apparatus. After a reaction chamber was evacuated to vacuum, the vacuum was replaced with H₂ gas, and the flow rate of the H₂ carrier gas and the pumping speed were regulated so as for the total pressure to be stabilized at 0.1 atm.

Next, while feeding a flow of a mixed gas composed of AsH₃ and H₂ carrier gas (total pressure: 0.1 atm, AsH₃ partial pressure: 2.5×10⁻⁴ atm), the substrate temperature was increased to 720° C.

Next, the flowing gas was changed over to a mixed gas composed of TMI gas, TMG gas, AsH₃ gas and H₂ carrier gas (total pressure: 0.1 atm, TMI partial pressure: 1.8×10⁻⁷ atm, TMG partial pressure: 6.9×10⁻⁷ atm, AsH₃ partial pressure: 1.3×10⁻⁴ atm). The mixed gas was introduced into the reaction chamber, and nanopillars formed of In_{0.35}Ga_{0.65}As were grown on the GaAs(111)B substrate.

After 60 minutes, the flowing gas was changed over to a mixed gas composed of AsH₃ gas and H₂ carrier gas (total pressure: 0.1 atm, AsH₃ partial pressure: 2.5×10⁻⁴ atm), and the growth of the nanopillars was terminated. The GaAs(111)B substrate was cooled as it was, and the GaAs(111)B substrate having the nanopillars grown thereon was taken out.

The lattice constant of the GaAs(111)B substrate is 5.653 Å, the lattice constant of In_{0.35}Ga_{0.65}As constituting the nanopillars is 5.795 Å, and the mismatch of the lattice constant of In_{0.35}Ga_{0.65}As in relation to the GaAs(111)B substrate is 2.5%.

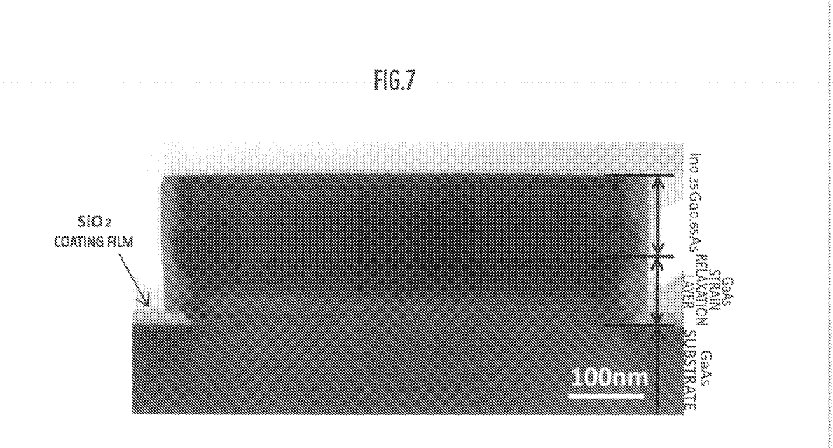

Next, the cross section of the GaAs(111)B substrate having the nanopillars grown thereon was observed with a transmission electron microscope (TEM). The obtained electron micrograph is shown in FIG. 5. From FIG. 5, no threading dislocation is found in the heterojunction interface between the GaAs(111)B substrate and the nanopillars formed of In_{0.35}Ga_{0.65}As.

### Comparative Example 1

In present Comparative Example, first, a InP(111)A substrate was cleaned, and then, by using an RF sputtering apparatus equipped with a SiO₂ target, an amorphous SiO₂ coating film was formed in a thickness of about 30 nm, on the InP(111)A substrate, as a transparent insulating material layer. Next, a positive resist was applied to the transparent insulating material layer by spin coating.

Next, on the positive resist, by using an EB drawing apparatus, a pattern of circular holes of 100 nm in diameter arranged with a pitch of 400 nm in a triangular lattice shape was drawn. After the drawing, the resist was developed, the amorphous SiO₂ coating film in the circular holes was removed by etching with a BHF aqueous solution, and after the etching, the resist was removed.

Next, the InP(111)A substrate having an amorphous SiO₂ coating film (transparent insulating material layer) formed thereon was set in a MOVPE apparatus. After a reaction chamber was evacuated to vacuum, the vacuum was replaced with H₂ gas, and the flow rate of the H₂ carrier gas and the pumping speed were regulated so as for the total pressure to be stabilized at 0.1 atm.

Next, while feeding a flow of a mixed gas composed of TBP gas and H₂ carrier gas (total pressure: 0.1 atm, TBP partial pressure: 2.5×10⁻⁴ atm), the substrate temperature was increased to 600° C. and the substrate was maintained at this temperature for 5 minutes. Next, while feeding a flow of a mixed gas composed of TBP gas and H₂ carrier gas (total pressure: 0.1 atm, TBP partial pressure: 1.3×10⁻⁴ atm), the temperature of the substrate was set at 550° C.

Next, the flowing gas was changed over to a mixed gas composed of TMI gas, AsH₃ gas and H₂ carrier gas (total pressure: 0.1 atm, TMI partial pressure: 3.0×10⁻⁷ atm, AsH₃ partial pressure: 1.3×10⁻⁴ atm). The mixed gas was introduced into the reaction chamber, and nanopillars formed of InAs were grown on the InP(111)A substrate.

After 20 minutes, the flowing gas was changed over to a mixed gas composed of AsH₃ gas and H₂ carrier gas (total pressure: 0.1 atm, AsH₃ partial pressure: 1.3×10⁻⁴ atm), and the growth of the nanopillars was terminated. The InP(111)A substrate was cooled as it was, and the InP(111)A substrate having the nanopillars grown thereon was taken out.

The lattice constant of the InP(111)A substrate is 5.869 Å, the lattice constant of InAs constituting the nanopillars is 6.058 Å, and the mismatch of the lattice constant of InAs in relation to the InP(111)A substrate is 3.2%.

Next, the cross section of the InP(111)A substrate having the nanopillars grown thereon was observed with a transmission electron microscope (TEM). The obtained electron micrograph is shown in FIG. 6. From FIG. 6, dislocation defect is found in the heterojunction interface between the InP(111)A substrate and the nanopillars formed of InAs.

In Example 1 and Comparative Example 1, the GaAs(111)B substrate or the InP(111)A substrate corresponds to the layered structure section of the present invention. Accordingly, from Example 1 and Comparative Example 1, it is obvious that when the mismatch of the lattice constant in the heterojunction interface between the layered structure section and the nanopillars is 2.5% or less, no dislocation defect occurs.

### Example 2

In present Example, first, a GaAs(111)B substrate was cleaned, and then, by using an RF sputtering apparatus equipped with a SiO₂ target, an amorphous SiO₂ coating film was formed in a thickness of about 30 nm, on the GaAs(111)B substrate, as a transparent insulating material layer. Next, a positive resist was applied to the transparent insulating material layer by spin coating.

Next, on the positive resist, by using an EB drawing apparatus, a pattern of circular holes of 650 nm in diameter arranged with a pitch of 1 μm in a triangular lattice shape was drawn. After the drawing, the resist was developed, the amorphous SiO₂ coating film in the circular holes was removed by etching with a BHF aqueous solution, and after the etching, the resist was removed.

Next, the GaAs(111)B substrate having an amorphous SiO₂ coating film (transparent insulating material layer) formed thereon was set in a MOVPE apparatus. After a reaction chamber was evacuated to vacuum, the vacuum was replaced with H₂ gas, and the flow rate of the H₂ carrier gas and the pumping speed were regulated so as for the total pressure to be stabilized at 0.1 atm.

Next, while feeding a flow of a mixed gas composed of AsH₃ gas and H₂ carrier gas (total pressure: 0.1 atm, AsH₃ partial pressure: 1.3×10⁻⁴ atm), the substrate temperature was increased to 750° C. Next, the flowing gas was changed over to a mixed gas composed of TMG gas, AsH₃ gas and H₂ carrier gas (total pressure: 0.1 atm, TMG partial pressure: 1.0×10⁻⁶ atm, AsH₃ partial pressure: 2.5×10⁻⁴ atm). The mixed gas was introduced into the reaction chamber, and nanopillars formed of GaAs crystal were grown as the strain relaxation layer on the GaAs(111)B substrate.

After 15 minutes, the flowing gas was changed over to a mixed gas composed of AsH₃ gas and H₂ carrier gas (total pressure: 0.1 atm, AsH₃ partial pressure: 1.3×10⁻⁴ atm), and the growth of the nanopillars formed of the GaAs crystal was terminated.

Next, while feeding the flow of the mixed gas composed of AsH₃ and H₂ carrier gas (total pressure: 0.1 atm, AsH₃ partial pressure: 1.3×10⁻⁴ atm), the substrate temperature was set at 720° C. Next, the flowing gas was changed over to a mixed gas composed of TMI gas, TMG gas, AsH₃ gas and H₂ carrier gas (total pressure: 0.1 atm, TMI partial pressure: 1.8×10⁻⁷ atm, TMG partial pressure: 7.3×10⁻⁷ atm, AsH₃ partial pressure: 1.3×10⁻⁴ atm). The mixed gas was introduced into the reaction chamber, and the nanopillars formed of In_{0.35}Ga_{0.65}As were grown on the ends of the nanopillars formed of GaAs crystal.

After 15 minutes, the flowing gas was changed over to a mixed gas composed of AsH₃ gas and H₂ carrier gas (total pressure: 0.1 atm, AsH₃ partial pressure: 1.3×10⁻⁴ atm), and the growth of the nanopillars was terminated. The GaAs(111)B substrate was cooled as it was, and the GaAs(111)B substrate having the nanopillars grown thereon was taken out.

The GaAs(111)B substrate and the GaAs crystal as the strain relaxation layer are matched in lattice constant with each other, and the lattice constant of the GaAs(111)B substrate is 5.653 Å, and the lattice constant of In_{0.35}Ga_{0.65}As constituting the nanopillars is 5.795 Å. Accordingly, the mismatch of the lattice constant of In_{0.35}Ga_{0.65}As in relation to the GaAs crystal (strain relaxation layer) is 2.5%. The diameter d of the inscribed circle C inscribed in the cross section of the nanopillar formed of GaAs crystal and the diameter d of the inscribed circle C inscribed in the cross section of the nanopillar formed of In_{0.35}Ga_{0.65}As were both 650 nm.

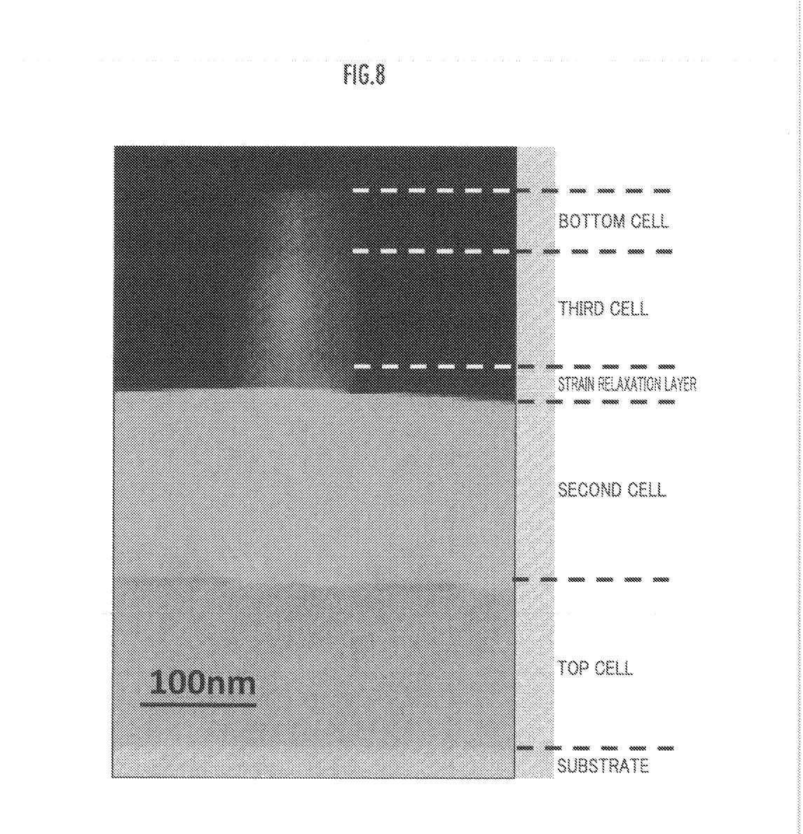

Next, the cross section of the GaAs(111)B substrate having the nanopillars grown thereon was observed with a transmission electron microscope (TEM). The obtained electron micrograph is shown in FIG. 7. From FIG. 7, no dislocation defect is found in the heterojunction interface in the GaAs(111)B substrate to which the nanopillars formed of In_{0.35}Ga_{0.65}As were joined through the intermediary of the nanopillars formed of GaAs crystal, as the strain relaxation layer.

In Example 2, the GaAs(111)B substrate corresponds to the layered structure section of the present invention. Accordingly, from Example 2, it is obvious that in the case where the mismatch of the lattice constant is 2.5% or less, when the diameter d of the inscribed circle C inscribed in the cross section of the nanopillar structure section is 0.65 μm or less, no dislocation defect occurs in the heterojunction interface.

### Example 3

In present Example, first a GaAs(111)B was cleaned, and then set in a MOVPE apparatus. After the reaction chamber was evacuated to vacuum, the vacuum was replaced with H₂ gas, and the flow rate of the H₂ carrier gas and the pumping speed were regulated so as for the total pressure to be stabilized at 0.1 atm.

Next, while feeding a flow of a mixed gas composed of AsH₃ gas and H₂ carrier gas (total pressure: 0.1 atm, AsH₃ partial pressure: 2.5×10⁻⁴ atm), the substrate temperature was increased to 650° C. Next, the flowing gas was changed over to a mixed gas composed of TMG gas, TMI gas, TBP gas and H₂ carrier gas (total pressure: 0.1 atm, TMG partial pressure: 1.4×10⁻⁶ atm, TMI partial pressure: 1.4×10⁻⁶ atm, TBP partial pressure: 6.5×10⁻⁵ atm). The mixed gas was introduced into the reaction chamber, and a thin film-shaped top cell formed of In_{0.48}Ga_{0.52}P was grown on the GaAs(111)B substrate.

After 15 minutes, the flowing gas was changed over to a mixed gas composed of TBP gas and H₂ carrier gas (total pressure: 0.1 atm, TBP partial pressure: 6.5×10⁻⁵ atm), and the growth of the top cell was terminated.

Next, while feeding the flow of the mixed gas composed of TBP gas and H₂ carrier gas (total pressure: 0.1 atm, TBP partial pressure: 1.0×10⁻³ atm), the substrate temperature was increased from 650° C. to 800° C. Next, the flowing gas was changed over to a mixed gas composed of TMG gas, AsH₃ gas and H₂ carrier gas (total pressure: 0.1 atm, TMG partial pressure: 3.9×10⁻⁶ atm, AsH₃ partial pressure: 7.5×10⁻⁵ atm). The mixed gas was introduced into the reaction chamber, and a thin film-shaped second cell formed of GaAs was grown on the top cell.

After 12 minutes, the flow gas was changed over to a mixed gas composed of AsH₃ gas and H₂ carrier gas (total pressure: 0.1 atm, AsH₃ partial pressure: 1.3×10⁻⁴ atm), and the growth of the second cell was terminated. The GaAs(111)B substrate was cooled as it was, and the GaAs(111)B substrate having the top cell and the second cell grown thereon was taken out.

Next, by using an RF sputtering apparatus equipped with a SiO₂ target, an amorphous SiO₂ coating film was formed in a thickness of about 30 nm, on the second cell, as a transparent insulating material layer. Next, a positive resist was applied to the transparent insulating material layer by spin coating.

Next, on the positive resist, by using an EB drawing apparatus, a pattern of circular holes of 150 nm in diameter arranged with a pitch of 400 nm in a triangular lattice shape was drawn. After the drawing, the resist was developed, the amorphous SiO₂ coating film in the circular holes was removed by etching with a BHF aqueous solution, and after the etching, the resist was removed.

Next, the GaAs(111)B substrate having the amorphous SiO₂ coating film (transparent insulating material layer) formed thereon was set in a MOVPE apparatus. After a reaction chamber was evacuated to vacuum, the vacuum was replaced with H₂ gas, and the flow rate of the H₂ carrier gas and the pumping speed were regulated so as for the total pressure to be stabilized at 0.1 atm.

Next, while feeding a flow of a mixed gas composed of AsH₃ gas and H₂ carrier gas (total pressure: 0.1 atm, AsH₃ partial pressure: 2.5×10⁻⁴ atm), the substrate temperature was increased to 750° C. Next, the flowing gas was changed over to a mixed gas composed of TMG gas, AsH₃ gas and H₂ carrier gas (total pressure: 0.1 atm, TMG partial pressure: 1.0×10⁻⁶ atm, AsH₃ partial pressure: 2.5×10⁻⁴ atm). Next, the mixed gas was introduced into the reaction chamber, and nanopillars formed of GaAs crystal were grown as the strain relaxation layer.

After 3 minutes, the flowing gas was changed over to a mixed gas composed of AsH₃ gas and H₂ carrier gas (total pressure: 0.1 atm, AsH₃ partial pressure: 1.0×10⁻⁴ atm), and the growth of the nanopillars formed of GaAs crystal was terminated.

Next, while feeding the flow of the mixed gas composed of AsH₃ gas and H₂ carrier gas (total pressure: 0.1 atm, AsH₃ partial pressure: 1.0×10⁻⁴ atm), the substrate temperature was set at 720° C. Next, the flowing gas was changed over to a mixed gas composed of TMI gas, TMG gas, AsH₃ gas and H₂ carrier gas (total pressure: 0.1 atm, TMI partial pressure: 2.9×10⁻⁷ atm, TMG partial pressure: 7.1×10⁻⁷ atm, AsH₃ partial pressure: 1.3×10⁻⁴ atm). The mixed gas was introduced into the reaction chamber, and the nanopillar-shaped third cell formed of In_{0.3}Ga_{0.7}As was grown on the ends of the nanopillars formed of GaAs crystal.

After 8 minutes, the flowing gas was changed over to a mixed gas composed of AsH₃ gas and H₂ carrier gas (total pressure: 0.1 atm, AsH₃ partial pressure: 1.3×10⁻⁴ atm), and the growth of the third cell was terminated.

Next, while feeding the flow of a mixed gas composed of AsH₃ gas and H₂ carrier gas (total pressure: 0.1 atm, AsH₃ partial pressure: 1.0×10⁻⁴ atm), the substrate temperature was set at 710° C. Next, the flowing gas was changed over to a mixed gas composed of TMI gas, TMG gas, AsH₃ gas and H₂ carrier gas (total pressure: 0.1 atm, TMI partial pressure: 6.1×10⁻⁷ atm, TMG partial pressure: 4.3×10⁻⁷ atm, AsH₃ partial pressure: 1.3×10⁻⁴ atm). The mixed gas was introduced into the reaction chamber, the nanopillar-shaped bottom cell formed of In_{0.6}Ga_{0.4}As was grown on the nanopillar ends of the third cell.

After 8 minutes, the flowing gas was changed over to a mixed gas composed of AsH₃ gas and H₂ carrier gas (total pressure: 0.1 atm, AsH₃ partial pressure: 1.3×10⁻⁴ atm), and the growth of the bottom cell was terminated.

The GaAs(111)B substrate was cooled as it was, and the GaAs(111)B substrate having the top cell, the second cell, the strain relaxation layer, the third cell and the top cell formed thereon was taken out.

The top cell, the second cell and the strain relaxation layer are matched in lattice constant with each other. On the other hand, the mismatch of the lattice constant of the third cell in relation to the strain relaxation layer is 2.2% and the mismatch of the lattice constant of the bottom cell in relation to the third cell is 2.1%.

Next, the cross section of the GaAs(111)B substrate having the top cell, the second cell, the strain relaxation layer, the third cell and the bottom cell formed thereon was observed with a transmission electron microscope (TEM). The obtained electron micrograph is shown in FIG. 8. From FIG. 8, it is obvious that in the GaAs(111)B substrate having the top cell, the second cell, the strain relaxation layer, the third cell and the bottom cell formed thereon, no dislocation defect is found in the heterojunction interface.

### Example 4

In present Example, first, a GaAs(111)B substrate was cleaned, and then, by using an RF sputtering apparatus equipped with a SiO₂ target, an amorphous SiO₂ coating film was formed in a thickness of about 30 nm, on the GaAs(111)B substrate, as a transparent insulating material layer. Next, a positive resist was applied to the transparent insulating material layer by spin coating.

Next, on the positive resist, by using an EB drawing apparatus, a pattern of circular holes of 200 nm in diameter arranged with a pitch of 400 nm in a triangular lattice shape was drawn. After the drawing, the resist was developed, the amorphous SiO₂ coating film in the circular holes was removed by etching with a BHF aqueous solution, and after the etching, the resist was removed.

Next, the GaAs(111)B substrate having an amorphous SiO₂ coating film (transparent insulating material layer) formed thereon was set in a MOVPE apparatus. After a reaction chamber was evacuated to vacuum, the vacuum was replaced with H₂ gas, and the flow rate of the H₂ carrier gas and the pumping speed were regulated so as for the total pressure to be stabilized at 0.1 atm.

Next, while feeding a flow of a mixed gas composed of AsH₃ gas and H₂ carrier gas (total pressure: 0.1 atm, AsH₃ partial pressure: 2.5×10⁻⁴ atm), the substrate temperature was increased to 750° C.

Next, the flowing gas was changed over to a mixed gas composed of TMG gas, AsH₃ gas, SiH₄ gas and H₂ carrier gas (total pressure: 0.1 atm, TMG partial pressure: 1.0×10⁻⁶ atm, AsH₃ partial pressure: 2.5×10⁻⁴ atm, SiH₄ partial pressure: 1.0×10⁻⁸ atm). The mixed gas was introduced into the reaction chamber, and nanopillars formed of n⁺-GaAs were grown as the strain relaxation layer on the GaAs(111)B substrate.

After 5 minutes, the flowing gas was changed over to a mixed gas composed of AsH₃ gas and H₂ carrier gas (total pressure: 0.1 atm, AsH₃ partial pressure: 1.0×10⁻⁴ atm), and the growth of the nanopillars formed of n⁺-GaAs was terminated.

Next, while feeding the flow of the mixed gas composed of AsH₃ gas and H₂ carrier gas (total pressure: 0.1 atm, AsH₃ partial pressure: 1.0×10⁻⁴ atm), the substrate temperature was set at 720° C. Next, the flowing gas was changed over to a mixed gas composed of TMI gas, TMG gas, AsH₃ gas, SiH₄ gas and H₂ carrier gas (total pressure: 0.1 atm, TMI partial pressure: 2.9×10⁻⁷ atm, TMG partial pressure: 7.1×10⁻⁷ atm, AsH₃ partial pressure: 1.2×10 atm, SiH₄ partial pressure: 7.5×10⁻⁹ atm). The mixed gas was introduced into the reaction chamber, and the nanopillars formed of n⁺-In_{0.3}Ga_{0.7}As were grown on the ends of the nanopillars formed of GaAs crystal.

After 12 minutes, the flowing gas was changed over to a mixed gas composed of AsH₃ gas and H₂ carrier gas (total pressure: 0.1 atm, AsH₃ partial pressure: 1.2×10⁻⁴ atm), and the growth of the nanopillars formed of n⁺-In_{0.3}Ga_{0.7}As was terminated.

Next, the flowing gas was changed over to a mixed gas composed of TMI gas, TMG gas, AsH₃ gas, DEZ (diethylzinc) gas and H₂ carrier gas (total pressure: 0.1 atm, TMI partial pressure: 2.9×10⁻⁷ atm, TMG partial pressure: 7.1×10⁻⁷ atm, AsH₃ partial pressure: 1.2×10⁻⁴ atm, DEZ partial pressure: 1.0×10⁻⁶ atm). The mixed gas was introduced into the reaction chamber, and the nanopillars formed of p-In_{0.3}Ga_{0.7}As were grown on the ends of the nanopillars formed of n⁺-In_{0.3}Ga_{0.7}As.

After 45 minutes, the flowing gas was changed over to a mixed gas composed of AsH₃ gas and H₂ carrier gas (total pressure: 0.1 atm, AsH₃ partial pressure: 1.2×10⁻⁴ atm), and the growth of the nanopillars formed of p-In_{0.3}Ga_{0.7}As was terminated.

Next, while feeding the flow of the mixed gas composed of AsH₃ gas and H₂ carrier gas (total pressure: 0.1 atm, AsH₃ partial pressure: 1.0×10⁻⁴ atm), the substrate temperature was increased to 750° C. Next, the flowing gas was changed over to a mixed gas composed of TMG gas, AsH₃ gas, DEZ gas and H₂ carrier gas (total pressure: 0.1 atm, TMG partial pressure: 1.0×10⁻⁶ atm, AsH₃ partial pressure: 2.5×10⁻⁴ atm, DEZ partial pressure: 5.0×10⁻⁶ atm). The mixed gas was introduced into the reaction chamber, and the nanopillars formed of p⁺-GaAs were grown on the ends of the nanopillars formed of p-In_{0.3}Ga_{0.7}As.

After 5 minutes, the flowing gas was changed over to a mixed gas composed of AsH₃ gas and H₂ carrier gas (total pressure: 0.1 atm, AsH₃ partial pressure: 1.0×10⁻⁴ atm), and the growth of the nanopillars formed of p⁺-GaAs was terminated.

Consequently, a plurality of the nanopillar structure sections in which to the nanopillars formed of n⁺-GaAs, the nanopillars formed of n⁺-In_{0.3}Ga_{0.7}As, the nanopillars formed of p-In_{0.3}Ga_{0.7}As and the nanopillars formed of p⁺-GaAs were joined were formed.

Next, while feeding the flow of the mixed gas composed of AsH₃ gas and H₂ carrier gas (total pressure: 0.1 atm, AsH₃ partial pressure: 1.0×10⁻⁴ atm), the substrate temperature was set at 550° C. Next, the flowing gas was changed over to a mixed gas composed of TMA gas, TMI gas, TBP gas and H₂ carrier gas (total pressure: 0.1 atm, TMA partial pressure: 1.4×10⁻⁷ atm, TMI partial pressure: 2.7×10⁻⁶ atm, TBP partial pressure: 1.0×10⁻⁴ atm). The mixed gas was introduced into the reaction chamber, and a passivation layer formed of AlInP was grown on the surface of the nanopillar structure section.

After 2 minutes, the flowing gas was changed over to a mixed gas composed of TBP gas and H₂ carrier gas (total pressure: 0.1 atm, TBP partial pressure: 1.0×10⁻⁴ atm), and the growth of the passivation layer was terminated. The GaAs(111)B substrate was cooled as it was, and the GaAs(111)B substrate having the passivation layer grown on the surface of the nanopillar structure sections was taken out.

Next, the GaAs(111)B substrate having the passivation layer grown on the surface of the nanopillar structure section was set in an atomic layer deposition apparatus, the reaction chamber was evacuated to vacuum, and the substrate temperature was increased to 300° C. Next, with a pulsing valve, TMA and H₂O were fed to the reaction chamber alternately in a pulsing manner, and thus Al₂O₃ was filled, as an insulating material composed of an inorganic compound, between the plurality of the nanopillar structure sections to form the reinforcing layer, and further, the plurality of the nanopillar structure sections were embedded in the reinforcing layer.

Next, the substrate having the reinforcing layer formed thereon was cooled, and the cooled substrate was taken out from the atomic layer deposition apparatus.

Next, the substrate having the reinforcing layer formed thereon was set in a reactive ion etching (RIE) apparatus, and only the Al₂O₃ forming the reinforcing layer was selectively etched by using CF₄ gas to expose the ends of the nanopillars formed of p⁺-GaAs. Next, an ohmic electrode was formed on the reinforcing layer, by using Au and Ti, so as to be connected to the tips of the nanopillars formed of p⁺-GaAs, and thus a mono junction solar cell was obtained.

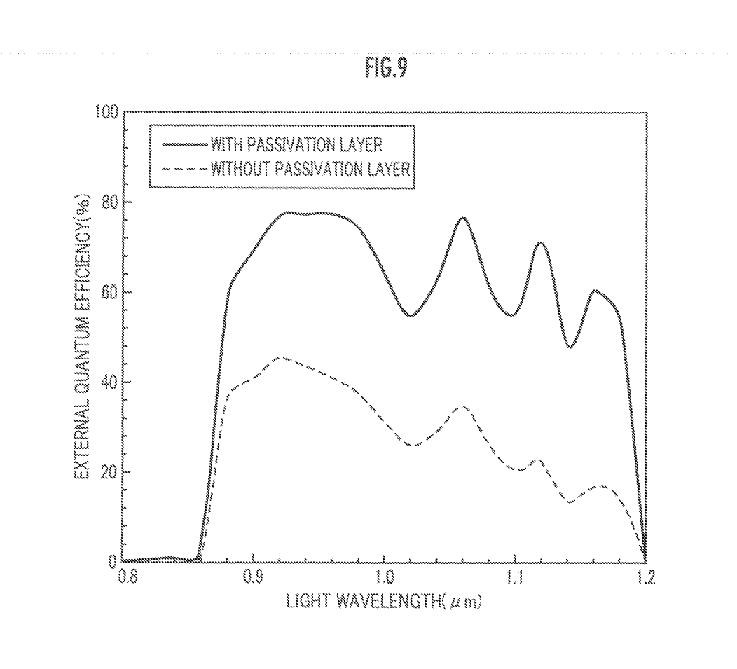

Next, the mono junction solar cell, obtained in present Example, having the passivation layer and a mono junction solar cell having the same structure as the structure of the mono junction solar cell obtained in present Example except that no passivation layer was involved were compared with respect to the external quantum efficiency. The results obtained are shown in FIG. 9.

As can be seen from FIG. 9, the external quantum efficiency is larger according to the mono junction solar cell having the passivation layer obtained in present Example, as compared to the mono junction solar cell having no passivation layer. Thus, obviously, according to the mono junction solar cell obtained in present Example, the passivation layer can suppress the recombination between electron and hole on the surface of the nanopillar structure sections. Accordingly, also obviously in the nanopillar structure sections of the multi-junction solar cell of the present invention, the effect of suppressing, by the passivation layer, the recombination of electron and hole on the surface of the nanopillar structure sections can be applied.

### Example 5

In present Example, first, a GaAs(111)B substrate was cleaned, and then, by setting the substrate in a plasma chemical vapor phase deposition (PCVD) apparatus, a SiNₓ coating film was formed as a transparent insulating material layer in a thickness of about 30 nm on the GaAs(111)B substrate, by using monosilane (SiH₄) gas, ammonia (NH₃) gas and hydrogen (H₂) gas. Next, by using an RF sputtering apparatus equipped with a SiO₂ target, a SiO₂ film was formed in a thickness of about 30 nm, on the SiN_{X} coating film. Next, a positive resist was applied to the SiO₂ film by spin coating.

Next, on the positive resist, by using an EB drawing apparatus, a pattern of circular holes of 200 nm in diameter arranged with a pitch of 400 nm in a triangular lattice shape was drawn. After the drawing, the resist was developed, the SiO₂ coating film in the circular holes was removed by etching with a BHF aqueous solution, and after the etching, the resist was removed.

Next, the substrate thus processed was set in an RIE apparatus, and by using CF₄ gas, the SiNₓ coating film in the circular holes was removed by etching. After the etching, the SiO₂ film was further removed by etching with a BHF aqueous solution.

Next, the GaAs(111)B substrate having an amorphous SiNₓ coating film (transparent insulating material layer) formed thereon was set in a MOVPE apparatus. After a reaction chamber was evacuated to vacuum, the vacuum was replaced with H₂ gas, and the flow rate of the H₂ carrier gas and the pumping speed were regulated so as for the total pressure to be stabilized at 0.1 atm.

Next, while feeding a flow of a mixed gas composed of AsH₃ gas and H₂ carrier gas (total pressure: 0.1 atm, AsH₃ partial pressure: 2.5×10⁻⁴ atm), the substrate temperature was increased to 750° C.

Next, the flowing gas was changed over to a mixed gas composed of TMG gas, AsH₃ gas and H₂ carrier gas (total pressure: 0.1 atm, TMG partial pressure: 1.0×10⁻⁶ atm, AsH₃ partial pressure: 2.5×10⁻⁴ atm). The mixed gas was introduced into the reaction chamber, and nanopillars formed of GaAs crystal were grown on the GaAs(111)B substrate as the strain relaxation layer.

After 15 minutes, the flowing gas was changed over to a mixed gas composed of AsH₃ gas and H₂ carrier gas (total pressure: 0.1 atm, AsH₃ partial pressure: 2.5×10⁻⁴ atm), and the growth of the nanopillars formed of GaAs crystal was terminated.

Next, while feeding the flow of the mixed gas composed of AsH₃ gas and H₂ carrier gas (total pressure: 0.1 atm, AsH₃ partial pressure: 2.5×10⁻⁴ atm), the substrate temperature was set at 720° C. Next, the flowing gas was changed over to a mixed gas composed of TMI gas, TMG gas, AsH₃ gas and H₂ carrier gas (total pressure: 0.1 atm, TMI partial pressure: 2.9×10⁻⁷ atm, TMG partial pressure: 7.1×10⁻⁷ atm, AsH₃ partial pressure: 1.3×10⁻⁴ atm). The mixed gas was introduced into the reaction chamber, and the nanopillars formed of In_{0.3}Ga_{0.7}As were grown on the ends of the nanopillars formed of GaAs crystal.

After 20 minutes, the flowing gas was changed over to a mixed gas composed of AsH₃ gas and H₂ carrier gas (total pressure: 0.1 atm, AsH₃ partial pressure: 1.3×10⁻⁴ atm), and the growth of the nanopillars formed of In_{0.3}Ga_{0.7}As was terminated. The GaAs(111)B substrate was cooled as it was, and the GaAs(111)B substrate having the nanopillars formed of In_{0.3}Ga_{0.7}As grown thereon was taken out.

Consequently, a plurality of the nanopillar structure sections in which to the nanopillars formed of GaAs crystal, the nanopillars formed of In_{0.3}Ga_{0.7}As were joined were formed.

Next, the GaAs(111)B substrate having the nanopillar structure sections formed thereon was set in an atomic layer deposition apparatus, and the reaction chamber was evacuated to vacuum.

Next, the substrate temperature was increased to 300° C. Next, with a pulsing valve, TMA and H₂O were fed to the reaction chamber alternately in a pulsing manner. In this case, the pulse time of TMA was set at 0.4 second, the pulse time of H₂O was set at 0.4 second, and the evacuation time was set at 1.0 second. The foregoing pulse time means the time during which the pulsing valve is opened for feeding TMA or H₂O to the reaction chamber, and the foregoing evacuation time means the time during which pulsing valve is closed for stopping the feeding of the material gas and for evacuating to vacuum the interior of the reaction chamber.

Consequently, the reinforcing layer was formed by filling Al₂O₃, as the insulating material made of an inorganic compound, between the plurality of the nanopillar structure sections.

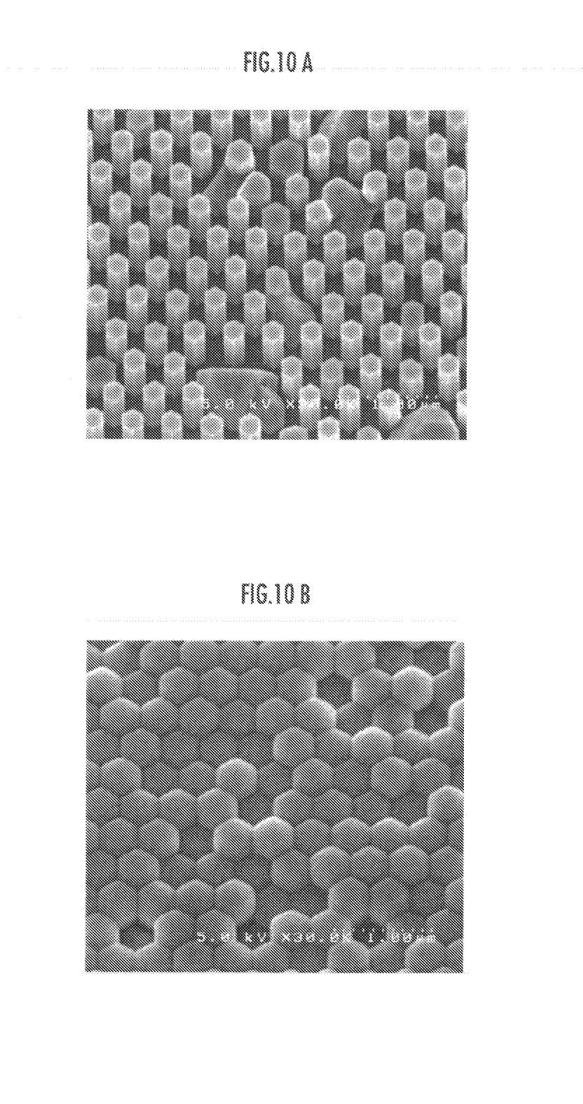

Next, the surface of the GaAs(111)B substrate was observed before and after the formation of the reinforcing layer, with a scanning electron microscope (SEM). The electron micrograph of the surface of the GaAs(111)B substrate before the formation of the reinforcing layer and the electron micrograph of the surface of the GaAs(111)B substrate after the formation of the reinforcing layer are shown in FIGS. 10A and 10B, respectively.

From FIGS. 10A and 10B, it is obvious that the reinforcing layer can be formed by filling an insulating material made of an inorganic compound between the plurality of the nanopillar structure sections, by using the atomic layer deposition apparatus.

### REFERENCE SIGNS LIST

1 Multi-junction solar cell
2 Top cell
3 Second cell
4 Layered structure section
5 Third cell
6 Bottom cell
7 Nanopillar structure section

1. A multi junction solar cell, comprising a plurality of compound semiconductor photovoltaic devices, different in band gap energy from each other, arranged in such a way that the nearer an incident side of sunlight, the larger the band gap energy, with each of the compound semiconductor photovoltaic devices being joined to each other through an intermediary of a tunnel junction layer,
wherein the multi-junction solar cell comprises a layered structure section including compound semiconductor photovoltaic devices matched in lattice constant with each other and laminated to be joined to each other, and a nanopillar structure section including a single compound semiconductor photovoltaic device or a plurality of compound semiconductor photovoltaic devices joined to each other; and
the nanopillar structure section comprises a compound semiconductor photovoltaic device mismatched in lattice constant with the compound semiconductor photovoltaic devices constituting the layered structure section, or a plurality of compound semiconductor photovoltaic devices mismatched in lattice constant with each other and joined to each other,

2. The multi junction solar cell according to claim 1, wherein in the compound semiconductor photovoltaic devices mismatched in lattice constant with each other, the mismatch of the lattice constant is 2.5% or less.

3. The multi junction solar cell according to claim 2, wherein when a diameter of an inscribed circle of a cross section of the nanopillar structure section is represented by d, the diameter d is 0.65 μm or less.

4. The multi junction solar cell according to claim 1,
wherein when the nanopillar structure section comprises a compound semiconductor photovoltaic device mismatched in lattice constant with the compound semiconductor photovoltaic devices constituting the layered structure section,
the compound semiconductor photovoltaic devices forming the nanopillar structure section are joined to the layered structure section through the intermediary of the nanopillar structure section comprising the compound semiconductor matched in lattice constant with the compound semiconductor photovoltaic devices constituting the layered structure section.

5. The multi junction solar cell according to claim 1, wherein the layered structure section is disposed on the sunlight incident side, and the nanopillar structure section is disposed on the side opposite to the sunlight incident side of the layered structure section.

6. The multi junction solar cell according to claim 1, wherein in the layered structure section, two compound semiconductor photovoltaic devices matched in lattice constant with each other are laminated to be joined to each other.

7. The multi junction solar cell according to claim 1, wherein the nanopillar structure section comprises a passivation layer to coat a surface of the nanopillar structure section.

8. The multi junction solar cell according to claim 1,
wherein the layered structure section comprises a first compound semiconductor photovoltaic device, forming an outermost layer, and a second compound semiconductor photovoltaic device laminated on and joined to the first compound semiconductor photovoltaic device;
the nanopillar structure section comprises a third compound semiconductor photovoltaic device joined to the second compound semiconductor photovoltaic device and a fourth compound semiconductor photovoltaic device joined to the third compound semiconductor photovoltaic device;
the first compound semiconductor photovoltaic device comprises In_{0.48}(Al_{α}Ga_{1-α})_{0.52}P(0≦α≦0.7);
the second compound semiconductor photovoltaic device comprises Al_{β}Ga_{1-β}As(0≦β≦0.45);
the third compound semiconductor photovoltaic device comprises Ga_{γ}In_{1-γ}As(0.65≦γ<1); and
the fourth compound semiconductor photovoltaic device comprises Ga_{δ}In_{1-δ}As(γ-0.35≦δ<γ).

9. The multi junction solar cell according to claim 1,
wherein the layered structure section comprises a first compound semiconductor photovoltaic device, forming an outermost layer, and a second compound semiconductor photovoltaic device laminated on and joined to the first compound semiconductor photovoltaic device;
the nanopillar structure section comprises a third compound semiconductor photovoltaic device joined to the second compound semiconductor photovoltaic device;
the first compound semiconductor photovoltaic device comprises In_{0.48}(Al_{α}Ga_{1-α})_{0.52}P(0≦α≦0.7);
the second compound semiconductor photovoltaic device comprises Al_{β}Ga_{1-β}As(0≦β≦0.45); and
the third compound semiconductor photovoltaic device comprises Ga_{γ}In_{1-γ}As(0.65≦γ<1).

10. A manufacturing method for a multi-junction solar cell, comprising:
a step of forming, by growing a crystal on a growth substrate, a layered structure section including compound semiconductor photovoltaic devices matching in lattice constant, laminated on and joined to each other;
a step of forming a coating layer, on a surface of the compound semiconductor photovoltaic devices forming the layered structure section, while exposing an area for forming thereon the nanopillar structure section to be joined to the layered structure section, and coating areas other than the area for forming the nanopillar structure section;
a step of forming a plurality of nanopillar structure sections each including at least one compound semiconductor photovoltaic device by epitaxially growing crystals on the area exposed from the coating layer on the surface of the compound semiconductor photovoltaic devices forming the layered structure section;
a step of forming a reinforcing layer for reinforcing the nanopillar structure sections by filling an insulating material in gaps between the plurality of nanopillar structure sections and by embedding the plurality of nanopillar structure sections with the insulating material;
a step of exposing tips of the plurality of nanopillar structure sections by partially removing the insulating material;
a step of forming a first electrode connected to the tips of the exposed plurality of nanopillar structure sections;
a step of forming a supporting substrate on the first electrode;
a step of exposing the layered structure section by removing the growth substrate; and
a step of forming a second electrode connected to the surface of the exposed layered structure section.

11. The manufacturing method for a multi-junction solar cell according to claim 10, wherein the reinforcing layer is formed by an atomic layer deposition method using an insulating material including an inorganic compound.
